(19) United States
(12) Patent Application Publication
(10) Pub. No.: US 2010/0244256 A1
(43) Pub. Date: Sep. 30, 2010

(54) SEMICONDUCTOR DEVICE AND MANUFACTURING METHOD THEREOF

(76) Inventors: Satoshi Kato, Yokohama-shi (JP); Atsuko Sakata, Yokohama-shi (JP); Masahiko Hasunuma, Yokohama-shi (JP); Noritake Oomachi, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/712,001

(22) Filed: Feb. 24, 2010

(30) Foreign Application Priority Data
Mar. 27, 2009 (JP) JP2009-080274

(51) Int. Cl. H01L 23/48; H01L 21/326; H01L 21/768

(52) U.S. Cl. 257/751; 438/466; 438/643; 257/E23.01; 257/E21.327; 257/E21.584

(57) ABSTRACT

A semiconductor device includes an interlayer insulating film formed above a semiconductor substrate. The interlayer insulating film has a concave portion. A barrier metal layer is formed along a bottom and a sidewall of the concave portion. The barrier metal layer has a first portion provided along the sidewall of the concave portion and a second portion provided along the bottom of the concave portion. A metal wiring layer is formed in the concave portion via the barrier metal layer. The first portion of the barrier metal layer is composed of a titanium nitride layer whose titanium content is more than 50 at %, and the second portion of the barrier metal layer is composed of a titanium nitride layer whose titanium content is relatively larger than the titanium content of the first portion or of a Ti layer.

### CROSS-REFERENCE TO RELATED APPLICATIONS

This application is based upon and claims the benefit of priority from the prior Japanese Patent Application No. 2009-080274, filed on Mar. 27, 2009; the entire contents of which are incorporated herein by reference.

### BACKGROUND OF THE INVENTION

In multilevel interconnection of a semiconductor integrated circuit (LSI), copper (Cu) wiring with a relatively low specific resistance is used. As a wiring structure, a (dual) damascene structure in which the Cu wiring is buried in trenches or vias formed in an interlayer insulating film is on the main stream. In the wiring of the damascene structure, since Cu easily diffuses into the interlayer insulating film due to its high activity, a barrier metal layer is formed at an interface between the Cu wiring and the interlayer insulating film. A wiring width in the damascene structure is getting finer with the miniaturization of the LSI. This has given rise to a strong demand for a barrier metal layer not only having an improved function of preventing the diffusion of Cu atoms into the interlayer insulating film but also having higher adhesiveness to the Cu wiring.

The adhesiveness of the barrier metal layer and the Cu wiring is important in enhancing electromigration (EM) resistance and stress migration (SM) resistance of the wiring. Further, it is desired that the barrier metal layer is formed with a small film thickness so as not to narrow a line width of the Cu wiring and is conformably formed with a uniform thickness on bottoms and sidewalls of the trenches and vias formed in the interlayer insulating film. US 2008/0023838 A1 discloses a barrier metal layer composed of a titanium nitride (TiNₓ) film whose titanium (Ti) content in all the components except oxygen and noble metal components is more than 50 at %. To form the TiNₓ film whose Ti content is more than 50 at %, a sputtering method with a non-nitride mode is employed.

In order to realize both reduced wiring resistance and improved adhesiveness, a TiN-based material is effective as a constituent material of the barrier metal layer. In particular, the TiNₓ film whose Ti content is more than 50 at % is advantageous in that it has high adhesiveness to metal wiring and can be conformably formed even when a low-dielectric insulating film is used. However, it has been found out that, when the barrier metal layer composed of the TiNₓ film whose Ti content is uniform is formed in the trenches and the vias, a margin realizing both reduced wiring resistance and improved adhesiveness is small, depending on the matching of a selected TiN composition with a device specification such as the wiring width or with a peripheral technique such as plating.

### BRIEF SUMMARY OF THE INVENTION

A semiconductor device according to an aspect of the present invention includes: a semiconductor substrate; an interlayer insulating film, formed above the semiconductor substrate, having a concave portion; a barrier metal layer, formed along a bottom and a sidewall of the concave portion, having a first portion provided along the sidewall and a second portion provided along the bottom; and a metal wiring layer formed in the concave portion via the barrier metal layer, wherein the first portion of the barrier metal layer is composed of a titanium nitride layer whose titanium content in all components except oxygen and a noble metal component is more than 50 at %, and the second portion of the barrier metal layer is composed of a titanium nitride layer whose titanium content in all components except oxygen and a noble metal component is more than 50 at % or composed of a titanium layer; and a volume average of the titanium content of the second portion is relatively larger than a volume average of the titanium content of the first portion.

A method of manufacturing a semiconductor device according to a first aspect of the present invention includes: forming an interlayer insulating film above a semiconductor substrate; forming a concave portion in the interlayer insulating film; forming a barrier metal layer along a bottom and a sidewall of the concave portion, including forming a first titanium nitride film whose titanium content in all components except oxygen and a noble metal component is more than 50 at %, and forming a second titanium nitride film whose titanium content in all components except oxygen and a noble metal component is larger than the titanium content of the first titanium nitride film or a titanium film so as to form the second titanium nitride film or the titanium film more along the bottom than along the sidewall; and forming a metal wiring layer in the concave portion via the barrier metal layer.

A method of manufacturing a semiconductor device according to a second aspect of the present invention includes: forming an interlayer insulating film above a semiconductor substrate; forming a concave portion in the interlayer insulating film; forming a barrier metal layer along a bottom and a sidewall of the concave portion, including forming a titanium nitride film whose titanium content in all components except oxygen and a noble metal component is more than 50 at % or a titanium film, and nitriding the titanium nitride film or the titanium film by using at least one selected from a nitrogen ion and a nitrogen radical so as to nitride the titanium nitride film or the titanium film formed along the sidewall relatively more than the titanium nitride film or the titanium film formed along the bottom; and forming a metal wiring layer in the concave portion via the barrier metal layer.

### BRIEF DESCRIPTION OF THE DRAWINGS

FIG. 1A to FIG. 1M are cross-sectional views showing a manufacturing method of a semiconductor device in a first embodiment.

FIG. 2 is a chart showing regions in a non-nitride mode and a nitride mode when a TiNₓ film is formed by sputtering.

FIG. 3 is a chart showing dependency of a specific resistance of the TiNₓ film on a nitrogen flow rate.

FIG. 4 is a chart showing a tendency of dependency of adhesiveness between the TiNₓ film and the Cu film on the composition and heat treatment temperature.

FIG. 5A and FIG. 5 are views used to describe an occurrence state of voids ascribable to poor adhesiveness of the barrier metal layer to a via bottom.

FIG. 6 is a cross-sectional view showing another structure in the manufacturing method of the first embodiment.

FIG. 7A and FIG. 7B are cross-sectional views showing a manufacturing method of a semiconductor device in a second embodiment.

### DETAILED DESCRIPTION OF THE INVENTION

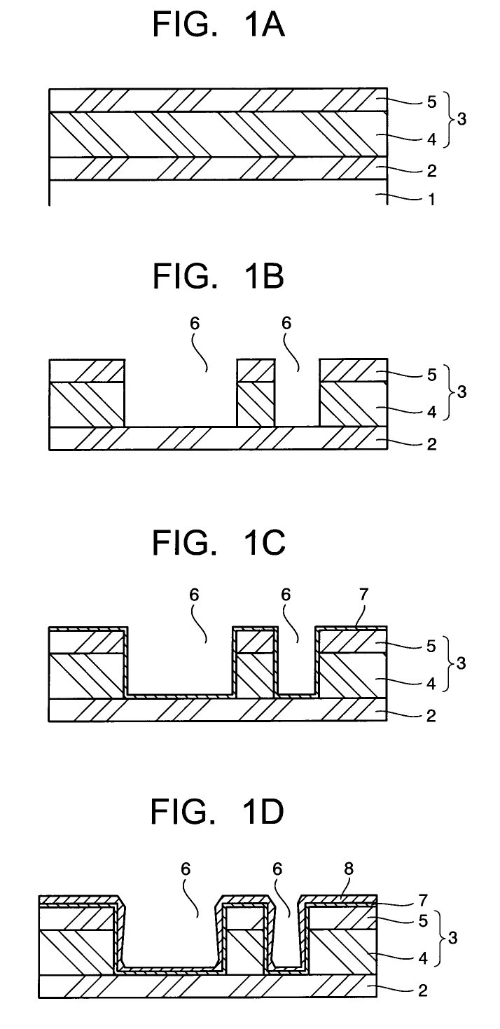

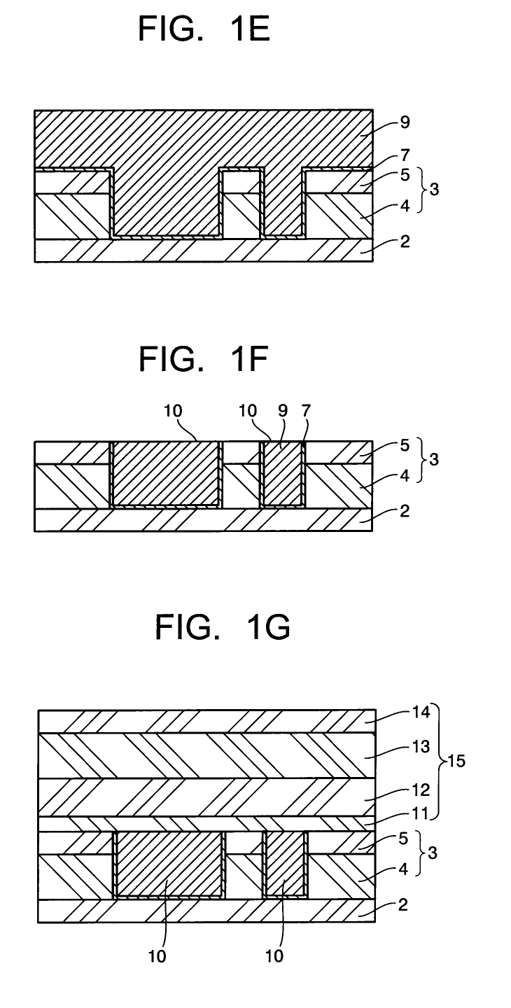

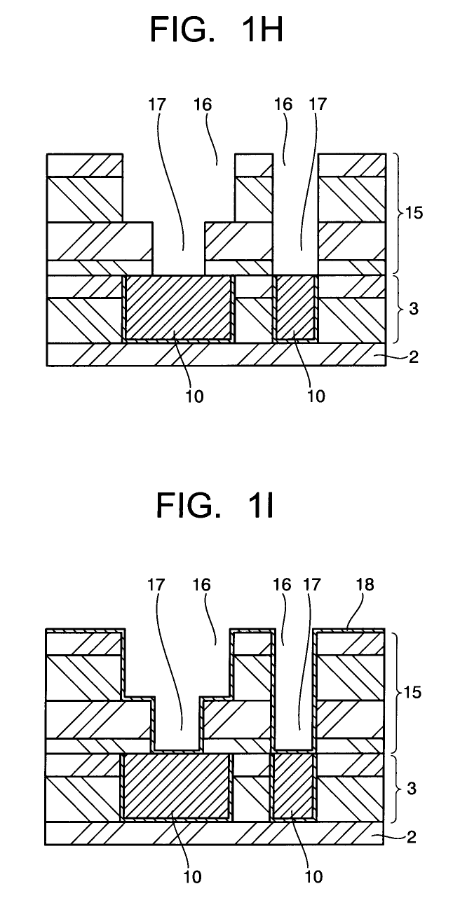

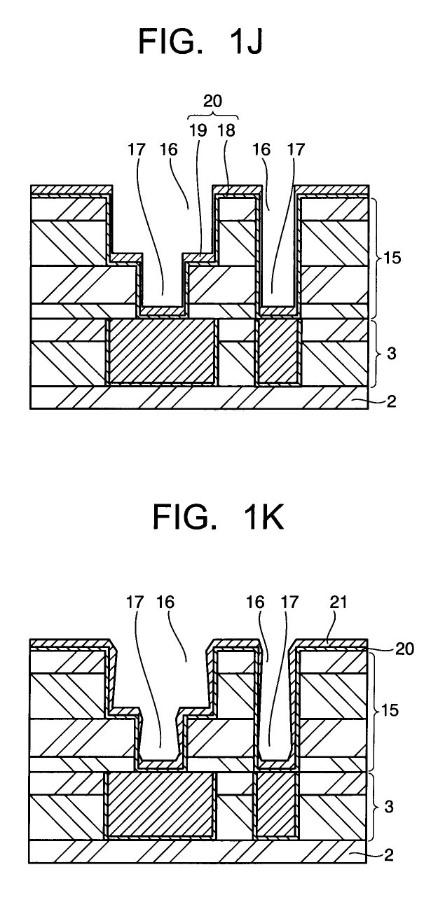

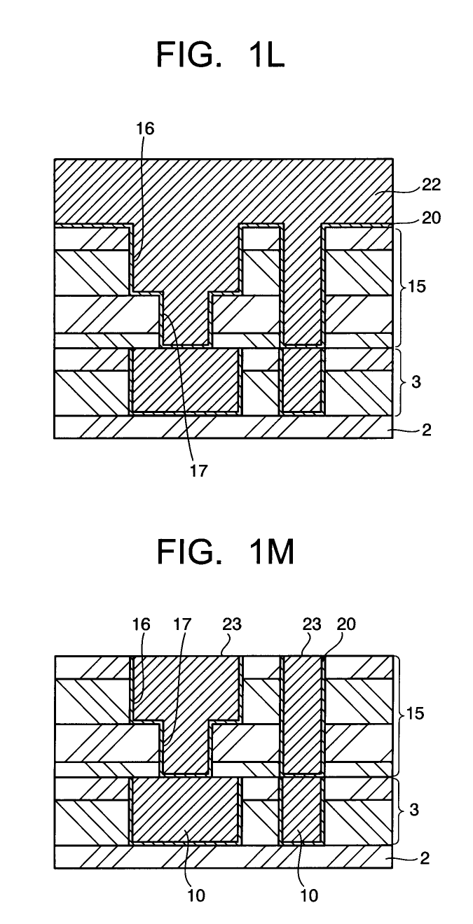

Hereinafter, embodiments for carrying out the present invention will be described with reference to the drawings. First, a first embodiment of the present invention will be described. FIGS. 1A to 1M show processes in a manufacturing method of a semiconductor device of the first embodiment in sequence. In the first embodiment, processes of forming multilevel interconnection of a dual damascene structure will be described.

In the first embodiment, a copper (Cu) wiring film is used as a metal wiring layer. As a barrier metal layer, a titanium nitride (TiNₓ) film whose titanium (Ti) content in all components except oxygen and noble metal components is more than 50 at %, or a lamination film of such a titanium nitride (TiNₓ) film and a titanium (Ti) film is used. As an insulating film, a polyarylene ether (PAE) film which is an organic low-dielectric insulating film, a carbon-containing silicon oxide (SiCO) film which is an inorganic low-dielectric insulating film, or the like is used.

The TiNₓ film whose Ti content is more than 50 at % and the Ti film can be manufactured easily by a sputtering method. In the following, a case where the TiNₓ film and the Ti film are formed by the sputtering method is mainly described. However, a film forming method of the TiNₓ and the Ti film is not limited to the sputtering method, and may be any other film forming method capable of forming a film with the same composition. The TiNₓ and the Ti film may contain oxygen derived from a reaction with oxidizing gas emitted by the insulating film or the like and may contain, as an additive element, a noble metal element (noble metal component) such as Ru, Pd, Pt, or Au. The Ti content of the TiNₓ film described below refers to the Ti content in all the components except oxygen and noble metal components, unless otherwise mentioned.

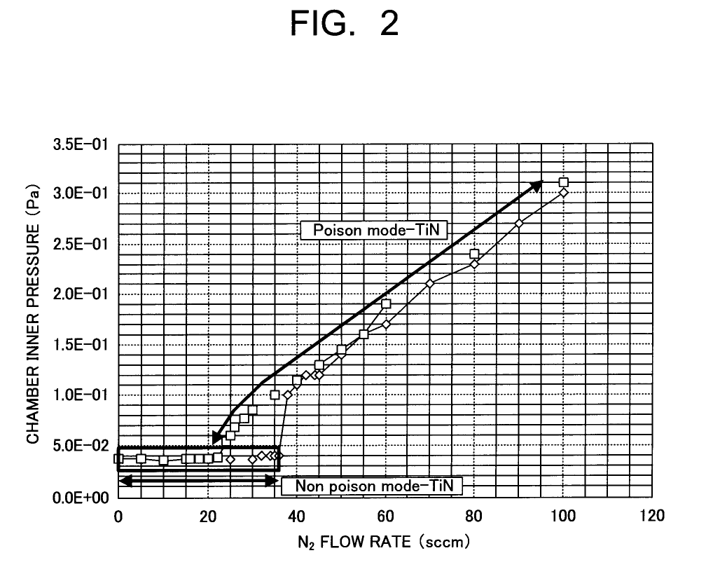

Generally, reactive sputtering of a nitride is divided into a nitride mode and a non-nitride mode. This is to classify modes of the sputtering according to the state of a surface of a metal target when sputtering is performed by introducing nitrogen into an apparatus. As shown in FIG. 2, in the plotting with the horizontal axis representing a N₂ flow rate and the vertical axis representing a chamber inner pressure, a pressure increase is small in regions where the nitrogen flow rate is low, while in regions where the nitrogen flow rate is high, the pressure increases. The regions where the pressure increase is small will be called the non-nitride mode, and the regions where the pressure increase is large will be called the nitride mode. The “non-nitride mode” and the “nitride mode” are also called a “non-poison mode” and a “poison mode” respectively.

In the non-nitride mode, a surface of a titanium target (metal target) is mainly composed of titanium (base metal) and is in the course of being nitrided. The surface of the target is sputtered substantially in a titanium state, and the titanium is nitrided in the course of reaching the substrate or on a surface of the substrate. On the other hand, in the nitride mode, the surface of the titanium target is fully nitrided, and the surface on which a nitride is formed is sputtered. In this case, a film with a proper composition with Ti:N being 1:1 is formed.

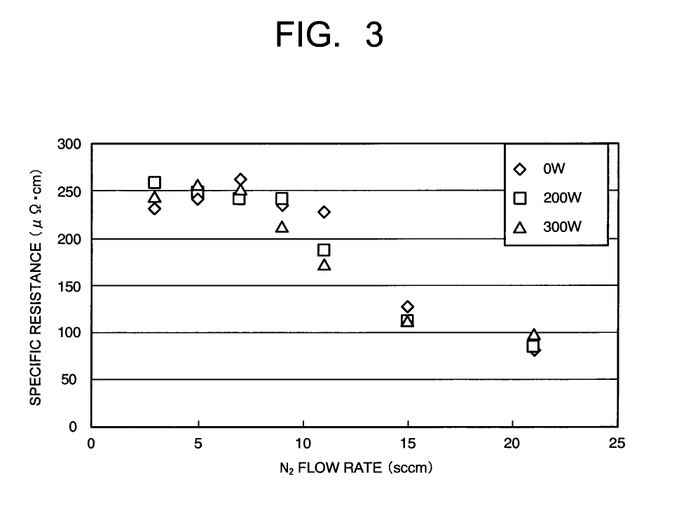

FIG. 3 shows dependency of a specific resistance of a titanium nitride (TiNₓ) film on a N₂ flow rate at the time of the sputtering. FIG. 3 shows relations between the specific resistance of the TiNₓ film and the N₂ flow rate when a substrate bias is 0 W, 200 W, and 300 W at the time of the sputtering, respectively. There is a tendency that, regardless of a bias condition, the resistance of the TiNₓ film increases with an increase of the N₂ flow rate at the time of the sputtering, and after reaching the peak, the resistance decreases.

The TiNₓ film whose Ti content is more than 50 at % is formed by a sputtering method with the non-nitride mode, that is, the “non-poison mode”. On the other hand, the TiNₓ film whose Ti content is 50 at % or less is formed by a sputtering method with the nitride mode, that is, the “poison mode”. In the description below, it is assumed that the TiNₓ film is formed by the sputtering method unless otherwise mentioned, and in this case, the terms, the TiNₓ film in the “non-nitride mode” and the “non-poison mode”, and the terms, the TiNₓ film in the “nitride mode” and the “poison mode”, will be used when necessary.

The TiNₓ film whose Ti content is more than 50 at % can be also formed by a chemical vapor deposition method (CVD method) or an atomic layer deposition method (ALD method), instead of the above-described sputtering method. When either of these methods is employed, it is possible to obtain the TiNₓ film whose Ti content is more than 50 at % by adjusting a partial pressure ratio of source gas and other gas, for example, a partial pressure ratio of N₂ or ammonia when the TiNₓ film is formed. It is also effective to employ a method of promoting the decomposition of the adsorbed source gas by plasma irradiation or radical irradiation.

Further, methods for obtaining the TiNₓ film whose Ti content is more than 50 at % include the following method. Specifically, N₂/Ar discharge is generated near a substrate which a Ti film is formed, and the Ti film is exposed to a nitrogen ion and a nitrogen radical in plasma, or a bias is applied to the substrate, to get the nitrogen ion and the nitrogen radical into the Ti film. It can be obtained the TiNₓ film having a desired composition by controlling a N₂/Ar flow rate and a pressure. Exposing a Ti film to a N₂ atmosphere can also obtain the TiNₓ film whose Ti content is more than 50 at %.

As shown in FIG. 1A, on a first silicon oxide film (SiO₂ film) 2 provided on a semiconductor substrate 1 such as a silicon (Si) substrate, a first PAE film 4 and a second SiO₂ film 5 are formed sequentially as a first interlayer insulating film 3. Electrodes (lower electrodes), though not shown, of a semiconductor element formed on the semiconductor substrate 1 are exposed to the first SiO₂ film 2. Next, as shown in FIG. 1B, by selective etching of the first PAE film 4 and the second SiO₂ film 5 employing a photolithography technique and reactive ion etching (RIE), first wiring trenches 6 are formed.

Next, as shown in FIG. 1C, along a surface of the second SiO₂ film 5 and sidewalls and bottoms of the first wiring trenches 6, a titanium (Ti) film 7 is formed as a first barrier metal layer. The Ti film 7 is formed while satisfactorily covering steps. Next, after a first copper (Cu) seed film 8 is formed in the first wiring trenches 6 as shown in FIG. 1D, a first copper (Cu) plating film 9 is formed by performing a burying process by copper (Cu) plating as shown in FIG. 1E.

Subsequently, the first Cu plating film 9 is subjected to heat treatment. A purpose of the heat treatment here is to increase a grain size of Cu so that a change of the first Cu plating film 9 caused by a time-dependent change of film quality due to self-aging or the like can be prevented in advance. In FIG. 1E, the whole Cu metal layer including the first Cu seed film 8 is shown as the first Cu plating film 9.

Thereafter, the Ti film 7 and the first Cu plating film 9 are subjected to a CMP process, whereby a first copper (Cu) wiring layer 10 filled in the first wiring trenches 6 is formed as shown in FIG. 1F. After going through the CMP process, the Ti film 7 and the first Cu plating film 9 constitute the first Cu wiring layer 10 filled in the first wiring trenches 6.

Next, as shown in FIG. 1G, on the first interlayer insulating film 3 having the first Cu wiring layer 10, a SiCN film 11, a SiCO film 12, a second PAE film 13, and a third SiO₂ film 14 are sequentially formed. The SiCN film 11 functions as a stopper film in a process employing a RIE method and as a Cu diffusion prevention film. The third SiO₂ film 14 functions as a protection film in a process employing a CMP method. The SiCN film 11, the SiCO film 12, the second PAE film 13, and the third SiO₂ film 14 constitute a second interlayer insulating film 15.

The second interlayer insulating film 15 can be composed only of at least one of the SiCO film 12 and the second PAE film 13. When the interlayer insulating film 15 is composed of a plurality of kinds of insulating films, using a highly hygroscopic porous film as at least one of the insulating films results in a large amount of oxidizing gas emitted from the insulating film. The “porous film” refers to a film having a large number of pores in order to reduce a relative dielectric constant to, for example, about 3 or lower. The second interlayer insulating film 15 preferably includes a low-dielectric insulating film (insulating film whose relative dielectric constant is 3 or lower) such as a porous film.

Next, as shown in FIG. 1H, the second interlayer insulating film 15 is selectively etched by employing a photolithography technique and RIE, whereby second wiring trenches 16 and vias 17 are formed. The vias 17 are formed so as to communicate with bottoms of the second wiring trenches 16. Part of a surface of the first Cu wiring layer 10 is exposed to the vias 17. A structure thus obtained is subjected to heat treatment in a vacuum atmosphere or a reducing atmosphere such as a H₂ gas atmosphere.

As a result of the heat treatment, H₂O contained in the second interlayer insulating film 15 is removed, oxidization seeds such as carbon-based residues originated from release of the bond at the time of forming the second wiring trenches 16 and the vias 17, and remaining in the second interlayer insulating film 15 are removed. By performing the heat treatment in the reducing atmosphere, it is also possible to reduce an oxide layer on the surface of the first Cu wiring layer 10 exposed to the bottoms of the vias 17.

Next, as shown in FIG. 1I, along the bottoms and the sidewalls of the second wiring trenches 16 and the vias 17 provided in the second interlayer insulating film 15, a first titanium nitride film (TiNₓ film) 18 in the non-nitride mode is formed. The first TiNₓ film 18 in the non-nitride mode is formed as part (first film) of the layer forming a second barrier metal layer, and its Ti content in all the components except oxygen and noble metal components is more than 50 at %.

Concretely, the first TiNₓ film 18 is formed as follows. A structure shown in FIG. 1H is carried into an ionization sputtering chamber to be placed on a susceptor set to a desired temperature, preferably a temperature lower than that of the heat treatment after forming the second wiring trenches 16 and the vias 17. The structure is sucked by the susceptor to be kept at the same temperature as the temperature of the susceptor. In this state, Ar gas for causing sputtering is led into the low-pressure sputtering chamber at a flow rate of, for example, 6 sccm to 8 sccm, and a slight amount of N₂, for example, N₂ at a flow rate of 1 sccm to 11 sccm is led in.

Then, by applying an ionization sputtering method, the TiNₓ film 18 with a thickness of, for example, 5 nm is formed with the substrate bias of not lower than 200 W nor higher than 1000 W under a cathode condition of, for example, 18 kW. At this time, an optimum substrate bias value for obtaining good coverage at the N₂ flow rate is appropriately selected. The TiNₓ film 18 is formed while satisfactorily covering steps. In this manner, a structure having a cross section shown in FIG. 1I is obtained.

Next, on the first TiNₓ film 18, a second TiNₓ film 19 in the non-nitride mode whose Ti content ratio is relatively high compared with that of the first TiNₓ film 18 is formed as shown in FIG. 1J. The second TiNₓ film 19 in the non-nitride mode is formed as part (second film) of the layer forming the second barrier metal layer, its Ti content in all the components except oxygen and noble metal components is more than 50 at %, and its Ti content is relatively large compared with that of the first TiNₓ film 18. As the second film which constitutes part of the second barrier metal layer, a Ti film may be employed instead of the TiNₓ film 19.

An amount of the second TiNₓ film (or Ti film) 19 formed on the first TiNₓ film 18 deposited on the bottoms of the second wiring trenches 16 and the vias 17 is relatively large, compared with that formed on the first TiNₓ film 18 deposited on the sidewalls of the second wiring trenches 16 and the vias 17. That is, a film forming condition under which the second TiNₓ film (or Ti film) 19 is not deposited much on the sidewalls of the second wiring trenches 16 and the vias 17 is selected. The second TiNₓ film 19 is formed as follows, for instance.

After the aforesaid first TiNₓ film 18 having good step coverage is formed, the second TiNₓ film 19 is formed in the same chamber or a different chamber while the vacuum state is kept. The second TiNₓ film 19 is formed with a lower substrate bias than that applied at the time of the formation of the first TiNₓ film 18, for example, with a substrate bias of less than 200 W (including zero) so that the TiNₓ film 19 is not formed much on the sidewalls of the second wiring trenches 16 and the vias 17 and is formed in a relatively larger amount along the bottoms than along the sidewalls. At this time, in order to increase a Ti amount contained in the second TiNₓ film 19, selected is, for example, a condition under which a flow rate of N₂ led in at the time of forming the second TiNₓ film 19 is made lower than that of forming the first TiNₓ film 18.

When 5 sccm is selected as the N₂ flow rate at the time of forming the first TiNₓ film 18, N₂ is led in at a flow rate of less than 5 sccm at the time of forming the second TiNₓ film 19. Under such a film forming condition, the second TiNₓ film 19 is formed to, for example, 5 nm. At this time, a TiN composition sometimes differs depending on a selected bias value, and an optimum substrate bias value for obtaining desired coverage at the N₂ flow rate is appropriately selected while the flow rate of N₂ led in at the time of the film formation has the relation such that the flow rate of N₂ is lower at the time of forming the second TiNₓ film 19 than at the time of forming the first TiNₓ film 18. In this manner, a structure having a cross section shown in FIG. 1J is obtained.

The second barrier metal layer 20 is composed of a lamination film of the first TiNₓ film 18 and the second TiNₓ film (or Ti film) 19. By forming the second TiNₓ film (or Ti film) 19 relatively more on the first TiNₓ film 18 deposited on the bottoms of the second wiring trenches 16 and the vias 17 than on the first TiNₓ film 18 deposited on the sidewalls, it is possible to obtain the second barrier metal layer 20 in which the Ti content of the portions, of the lamination film of the first TiNₓ film 18 and the second TiNₓ film (or Ti film) 19, deposited on the bottoms (second portions) is larger than the Ti content of the portions, of the lamination film of the first TiNₓ film 18 and the second TiNₓ film (or Ti film) 19, deposited on the sidewalls (first portions).

Next, while the vacuum state is kept, the structure shown in FIG. 1J is carried into a chamber for wiring formation, and while the structure is kept at a desired temperature, a second copper (Cu) seed film 21 is formed on the second barrier metal layer 20 as shown in FIG. 1K. The second Cu seed film 21 is formed by a physical vapor deposition method (PVD method), a CVD method, an ALD method, or the like so as to have a desired film thickness, for example, a film thickness of about 60 nm. Next, as shown in FIG. 1L, by employing a plating method, a second copper (Cu) plating film 22 is buried in the second wiring trenches 16 and the vias 17. In FIG. 1L, the whole Cu wiring layer including the second Cu seed film 21 is shown as the second Cu plating film 22.

Then, in order to prevent variation of the second Cu plating film 22 caused by a time-dependent change of film quality due to self-aging or the like, a heat treatment process for increasing the grain size of Cu in advance (annealing after plating) is performed. This annealing is performed in a vacuum atmosphere, a nitrogen gas atmosphere, or a N₂/H₂ gas atmosphere while the temperature is kept at 150° C. to 400° C. for about 60 minutes. It goes without saying that the optimum temperature and the optimum duration of this annealing condition changes as the plating condition variously changes.

Thereafter, the second barrier metal layer 20 and the second Cu plating film 22 are subjected to CMP for planarization, whereby a second Cu wiring layer 23 filled in the second wiring trenches 16 and the vias 17 is formed as shown in FIG. 1M. By going though the CMP process, the second barrier metal layer 20 and the second Cu plating film 22 constitute the second Cu wiring layer 23 with a dual damascene structure. Incidentally, though FIG. 1M shows the two-layer wiring structure, the number of stacked layers of the multilevel interconnection is not limited to this. The number of layers of the wiring layer can be increased by the repetition of the processes shown in FIG. 1G to FIG. 1M. The wiring structure is not limited to the dual damascene structure and may be a single damascene structure.

As described above, in the first embodiment, two kinds of the films (the TiNₓ film in the non-nitride mode or the Ti film) having a magnitude relation in the Ti content are used depending on the coverage. Consequently, when the areas of the barrier metal layer 20, that is, the barrier metal layer 20 on the bottoms and that on the sidewalls are individually seen, it is possible to obtain the barrier metal layer 20 in which the Ti content in areas on the bottoms (second portions) is relatively larger than the Ti content of areas on the sidewalls (first portions), in the volume of the whole lamination film of the first TiNₓ film 18 and the second TiNₓ film (or Ti film) 19. By employing such a barrier metal layer 20, the following advantages can be obtained.

Specifically, the wiring width becomes finer with the miniaturization of the element, and in the trench structure before the wiring is buried therein, an area of the trench sidewall surfaces becomes relatively large, compared with a wiring volume. When grains of the Cu film are grown in the annealing process after the plating, in the damascene wiring, crystal gains grow from three directions, that is, from the trench sidewall surfaces and the trench bottom surface. At this time, as the wiring becomes more microscopic, the growth from the trench sidewall surfaces contributes more. Therefore, in discussing wiring resistance, it is important how barrier metal in the trenches (barrier metal at least on the trench sidewall surfaces) is formed.

When the TiNₓ film in the non-nitride mode whose Ti content is relatively large is used, more Ti diffusion to the Cu wiring occurs and adhesiveness between the barrier metal and Cu becomes better, compared with a case where the TiNₓ film in the non-nitride mode whose Ti content is relatively small is used. Therefore, EM resistance and SM resistance which are merits of TiN-based barrier metal are improved, while the grain growth of the Cu wiring is suppressed owing to the good adhesiveness between the barrier metal and Cu. In particular, in the annealing process after the plating, re-growth of the Cu grains near the barrier metal is easily suppressed, and resistance of the Cu wiring becomes high, compared with a case where the TiNₓ film in the non-nitride mode whose Ti content is relatively small is used. For example, when the wiring width is set to 75 nm or less, this tendency is prominent.

Conversely, when the TiNₓ film in the non-nitride mode whose Ti content is relatively small is used, Ti diffusion to the Cu wiring is suppressed and thus adhesiveness between the barrier metal and Cu lowers, compared with the case where the TiNₓ film in the non-nitride mode whose Ti content is relatively large is used. Therefore, the effect of improving EM and SM which are the merits of the TiN-based barrier metal is not obtained much. However, the lowered adhesiveness between the barrier metal and Cu makes the grain growth of the Cu wiring relatively easy, and therefore, the resistance of the Cu wiring lowers.

Therefore, the TiNₓ film in the non-nitride mode whose Ti content is large, that is, the TiNₓ film on the bottoms of the trenches and the vias is used as a Ti diffusion source to the Cu wiring, and Ti is supplied mainly therefrom. On the other hand, the TiNₓ film in the non-nitride mode whose Ti content is relatively small compared with the TiNₓ film on the bottoms of the trenches and the vias is used on the trench sidewall. At this time, by employing the composition that relatively easily causes the grain growth of the Cu film, within a range where good adhesiveness is obtained, the grain growth of the Cu wiring is easily caused. By such a structure, high reliability and low resistance can be realized even in the microscopic wiring.

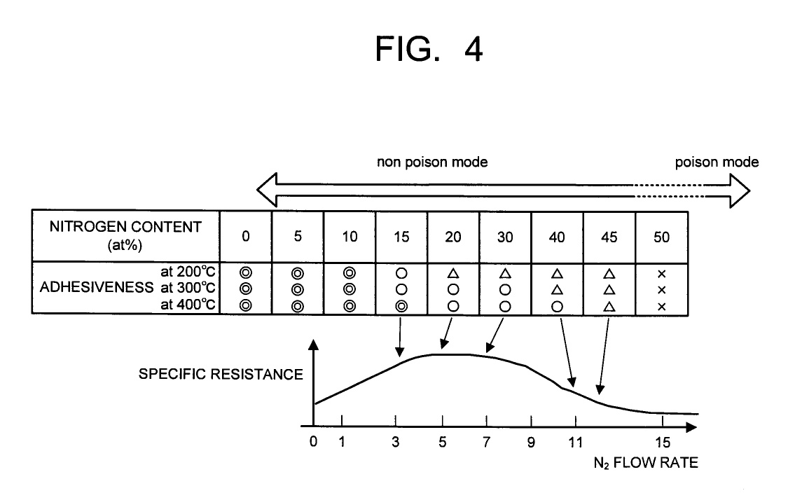

A TiNₓ composition is selected from composition ranges shown in FIG. 4, for instance, and the composition is set so that the Ti content of the TiNₓ film on the sidewalls becomes relatively smaller than the Ti content of the TiNₓ film on the bottoms of the trenches and the vias. FIG. 4 shows a summary of a cohesion tendency (adhesiveness) when films with various TiNₓ compositions are formed under the combinations of N₂ flow rates and substrate biases, a Cu film (plating film) with a 10 nm thickness is formed on each of these films, and thereafter, about one-hour heat treatment is performed in a H₂/N₂ gas atmosphere (H₂=3 vol %) at temperatures of about 200° C., about 300°, and about 400° C., and schematically shows tendencies of specific resistance corresponding the above conditions.

As is apparent from FIG. 4, the larger the Ti content is, the better the adhesiveness between the TiNₓ film and Cu is. Further, the adhesiveness between the TiNₓ film and Cu depends on the heat treatment temperature, and as the heat treatment temperature is higher, a preferable Ti composition (nitrogen composition) range becomes wider. In order to ensure the adhesiveness between the TiNₓ film and Cu, it is preferable to perform the heat treatment once or more at a temperature of 200° C. or higher at which not only the diffusion of Ti to the Cu wiring is caused but also a generation reaction of a compound begins to occur on an interface between the TiNₓ film in the non-nitride mode and the Cu film (plating film).

FIG. 4 shows the relation between the surface composition of the barrier metal layer (TiNₓ film) and the adhesiveness, and what is necessary is only that the aforesaid magnitude relation of the Ti content in terms of an average composition (volume average) as the whole film volume is kept between the respective areas of the barrier metal layer 20. The reason why the Ti content is represented by an average composition of the whole film volume of each area is as follows. As for the barrier metal layer 20 on the sidewalls, when, for example, a film formation condition under which the second TiNₓ film 19 is formed on the sidewalls discontinuously or in an island form is selected, there occurs a case where both of the first TiNₓ film 18 and the second TiNₓ film 19 are in contact with the Cu wiring layer 23. In such a state, it is more appropriate to discuss in terms of the average composition of the whole film deposited on the sidewalls rather than the surface composition.

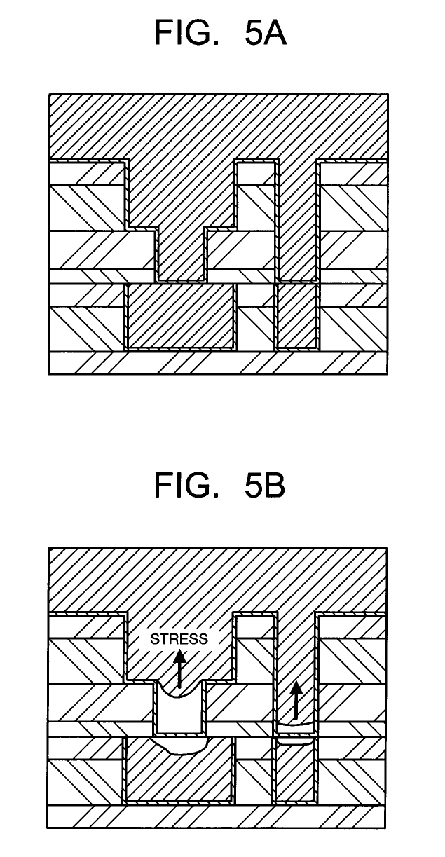

As a Ti diffusion source to the Cu wiring, the TiNₓ film (or Ti film) deposited on the bottoms of the trenches and the bottoms of the vias is used, but a large Ti content is necessary especially on the via bottoms. This is because of the following reason. FIG. 5A and FIG. 5B are views showing simulation of a state where voids are generated in the via bottoms and a lower wiring when barrier metal having low adhesiveness is used. The low adhesiveness between the Cu wiring and the barrier metal on the via bottoms causes a defect that Cu is sucked up and a defect that voids are generated in via lower portions in contact with the lower wiring, as shown in FIG. 5B, which lowers reliability. In particular, since the via bottoms in contact with the lower wiring comes into contact with the lower wiring having a damage or the like, and in addition, stress is easily concentrated thereon because of their shape, and consequently voids are easily generated therein.

In order to prevent the generation of micro-voids which become generation origins of the aforesaid voids, it is important to enhance adhesiveness between the barrier metal and the Cu wiring. Therefore, near the vias, it is preferable to select the TiNₓ composition having a large Ti content which emphasizes the adhesiveness. On the via bottoms, the TiNₓ composition is defined by the average composition as the whole film volume of the barrier metal on the bottoms. This is because, when bias sputtering or the like is employed as the PVD process, re-sputtering easily occurs from the via bottoms and mixing of the films is likely to occur and therefore it is more appropriate to discuss in terms the average composition as the whole film volume on the via bottoms.

As described above, in order to lower the resistance of the Cu wiring layer 23, the Ti content of the barrier metal layer (TiNₓ film) 20 on the sidewalls of the wiring trenches 16 and the vias 17 is controlled to be relatively small, and in order to enhance reliability, the Ti content of the barrier metal layer (TiNₓ film) 20 on the bottoms of the wiring trenches 16 and the vias 17 is controlled to become relatively large. In order to make the Ti content of the TiNₓ film on the sidewalls relatively smaller than that of the TiNₓ film on the bottoms, it is also effective to make the film thickness of the first TiNₓ film 18 on the trench bottoms and the via bottoms smaller than that on the sidewalls. Methods for obtaining such a structure include the following method, for instance.

Specifically, after the first TiNₓ film 18 is formed, Ar gas is led into a chamber at a flow rate of about 6 sccm to about 8 sccm, for instance, and the surface of the first TiNₓ film 18 is etched by Ar ions under a condition that a substrate bias is 500 W to 1000 W, for example, 1000 W under a cathode condition of, for example, 0 kW to 5 kW. Increasing the substrate bias promotes the etching of the TiNₓ film 18 on the bottoms more than on the sidewalls Further, depending on the condition, it is possible to remove the TiNₓ film 18 on the bottoms by etching while leaving the TiNₓ film 18 on the sidewalls. The flow rate of Ar and an optimum substrate bias value are selected appropriately.

Thereafter, as shown in FIG. 1J, the second TiNₓ film (or Ti film) 19 in the non-nitride mode whose Ti content is relatively large is formed. The film thickness of the second TiNₓ film (or Ti film) 19 deposited on the bottoms of the wiring trenches 16 and the vias 17 increases by an amount by which the film thickness of the first TiNₓ film 18 on the bottoms of the wiring trenches 16 and the vias 17 is reduced. This can make the Ti content of the barrier metal layer (TiNₓ film) on the bottoms relatively large.

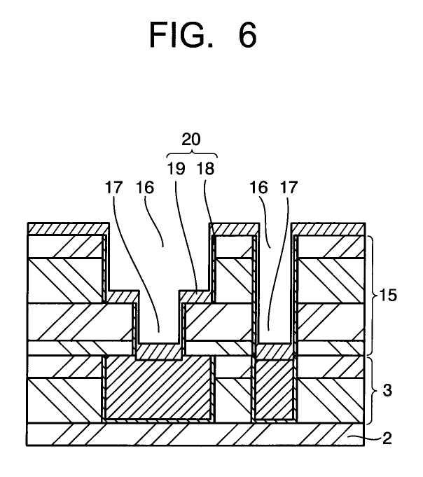

In particular, removing the first TiNₓ film 18 deposited on the bottoms of the vias 17 as shown in FIG. 6 allows the selection of various biases at the time of forming the second TiNₓ film (or Ti film) 19. This makes it possible to more effectively obtain the barrier metal layer 20 whose portion on the via bottoms has a relatively high Ti ratio and whose portions on the sidewalls have a relatively low Ti ratio. Further, when the first TiNₓ film 18 deposited on the bottoms of the vias 17 is removed by etching, part of the first Cu wiring layer 10 is sometimes etched as well. As a result, part of the second TiNₓ film (or Ti film) 19 penetrates in the first Cu wiring layer 10, which makes it possible to more effectively prevent the generation of voids in the via lower portions.

The first embodiment is an application example to the semiconductor device with the dual damascene structure, and therefore, in the barrier metal layer (TiNₓ film) 20, the Ti content of the portion deposited on the bottoms of the wiring trenches 16 and the vias 17 (second portions) is made relatively larger than the Ti content of the portion deposited on the sidewalls of the wiring trenches 16 and the vias 17 (first portions). When single damascene wiring or single-level interconnection is formed, by making the Ti content on the bottoms of the wiring trenches relatively larger than the Ti content on the sidewalls of the wiring trenches, it is similarly possible to provide a semiconductor device realizing high reliability and low resistance. Concave portions in which the barrier metal layer (TiNₓ film) having the portions (areas) different in Ti content is formed may be the wiring trenches including the vias or may be only the wiring trenches.

Next, a method of manufacturing a semiconductor device according to a second embodiment of the present invention will be described. In the second embodiment, as a result of the above-described processes shown in FIG. 1A to FIG. 1H, the structure shown in FIG. 1H is fabricated. Processes up to here are performed in the same manner as in the first embodiment.

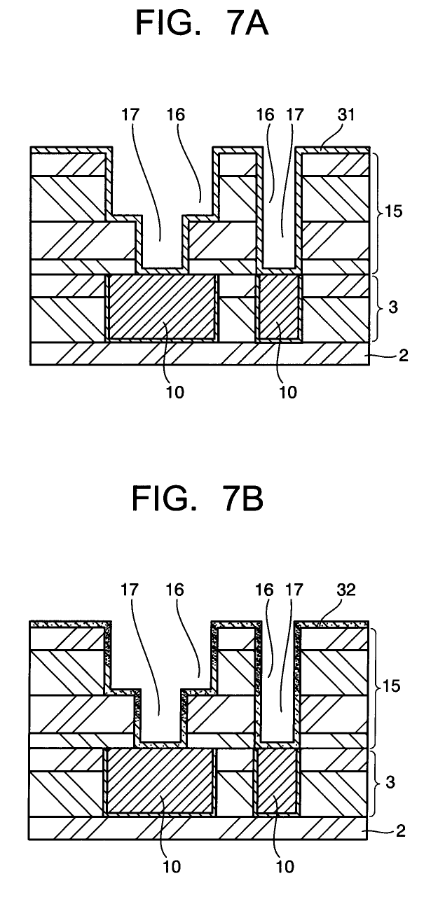

As shown in FIG. 7A, along the bottoms and the sidewalls of the second wiring trenches 16 and the vias 17 provided in the second interlayer insulating film 15 of the structure shown in FIG. 1H, a titanium nitride (TiNₓ) film 31 in a non-nitride mode is formed. The TiNₓ film 31 is formed while satisfactorily covering steps. The TiNₓ film 31 is formed in the same manner as the first TiNₓ film 18 in the first embodiment. Instead of the TiNₓ film 31, a Ti film may be formed in the second wiring trenches 16 and the vias 17.

Next, a slight amount of N₂ at a flow rate of, for example, 1 sccm to 11 sccm is continuously led into the same ionization sputtering chamber, and N₂/Ar discharge is generated near a substrate under a bias condition that a substrate bias is as week as about 0 W to about 200 W under, for example, a 0.1 kW cathode condition. At this time, the discharge may be maintained by generating plasma in a high-pressure area. Alternatively, even if the pressure is low, if the chamber has a structure stabilizing plasma such as a coil, the discharge can be maintained without any continuous application of cathode DC.

At this time, since only a 0 W or a weak bias is applied to the substrate, a surface of the TiNₓ film (or Ti film) 31 on the substrate or in relatively upper portions in the trenches is nitrided. Further, when weak DC is applied at this time, Ti emitted from a target adheres to the trench bottoms and the via bottoms, so that a nitrogen content of the TiNₓ film (or Ti film) 31 along the sidewalls becomes relatively large. The nitridation may be also performed in a different ionization sputtering chamber while a vacuum state is kept, and the same effect is obtained in this case.

By nitriding the TiNₓ film (or Ti film) 31 on the sidewalls relatively more than the TiNₓ film (or Ti film) 31 on the trench bottoms and the via bottoms as described above, it is possible to obtain a barrier metal layer (the TiNₓ film in the non-nitride mode or the TiNₓ film based on the Ti film) 32 in which the Ti content differs depending on the areas (the first portions and the second portions) as shown in FIG. 7B. Thereafter, by performing the processes shown in FIG. 1K to FIG. 1M, it is possible to obtain a semiconductor device realizing high reliability and low resistance as in the first embodiment.

Instead of the above-described nitridation by the ion components, surface nitridation by radical components can also provide the same effect. In an ionization sputtering chamber, the ion components and the radical components are not separated from each other, but the surface treatment performed by leading radicals generated by using, for example, a discharge tube into the chamber causes no Ti deposition on the trench bottoms and the via bottoms unlike the aforesaid nitridation. However, as an aspect ratio increases, the radical components are more difficult to reach the trench bottoms and the via bottoms, so that effective gradation of nitridation occurs. Consequently, the Ti component of the barrier metal layer on the sidewalls is relatively reduced, so that the structure realizing both lower wiring resistance and improved reliability is obtained.

The same effect can be obtained also by exposing the TiNₓ film (or Ti film) 31 to a N₂ atmosphere. In the pattern having a very large aspect ratio, the N₂ gas is more difficult to reach the via bottoms like the nitride radical, so that effective gradation of nitridation occurs. Therefore, the structure realizing both lower wiring resistance and improved reliability is obtained.

The second embodiment is applied to the semiconductor device with the dual damascene structure similarly to the first embodiment, a nitridation amount of the TiNₓ film 31 is made relatively large in its portions deposited on the sidewalls of the wiring trenches 16 and the vias 17, compared with that in its portions deposited on the bottoms of the wiring trenches 16 and the vias 17. When single damascene wiring or single wiring is used, by making a nitridation amount on the sidewalls of the wiring trenches relatively large compared with that on the bottoms of the wiring trenches, it is similarly possible to provide a semiconductor device realizing high reliability and low resistance. The concave portions in which the barrier metal layer (TiNₓ film) having the portions different in nitridation amount, in other words, the barrier metal layer having the portions different in the Ti content is formed may either the wiring trenches including the vias or only the wiring trenches.

Next, a preferable composition of the TiNₓ film in the non-nitride mode in the first and second embodiments will be described. As described in the first embodiment as well, weak adhesiveness of the via bottoms is likely to cause a defect that Cu is sucked up and a defect that voids are generated in the via lower portions in contact with the lower wiring as shown in FIG. 5B. This lowers reliability of the wiring.

In view of preventing the occurrence of the above-described defects, a nitrogen (N) content (N content in all the components except oxygen and noble metal components) of the titanium nitride (TiNₓ) film deposited on the bottoms of the concave portions is preferably less than 40 at %. The TiNₓ film whose N content is less than 40 at % can exhibit excellent adhesiveness when the annealing temperature after the plating is increased up to about 300° C. as shown in FIG. 4. The N content of the TiNₓ film is more preferably less than 20 at % with which the adhesiveness at the annealing temperature of 200° C. or higher becomes good.

On the other hand, there is a tendency that, as the Ti content of the TiNₓ film is smaller, the wiring resistance becomes lower as described in the first embodiment, and therefore, the use of a barrier metal layer composed of a TiNₓ film whose Ti content is uniform has a difficulty in realizing both good adhesiveness and wiring resistance. Therefore, the barrier metal layer on the sidewalls of the concave portions is composed of the first TiNₓ layer whose Ti content is relatively reduced within a range in which good adhesiveness is obtained. Then, the barrier metal layer on the bottoms of the concave portions is composed of the second TiNₓ layer whose Ti content is larger than that of the first TiNₓ layer or of the Ti layer. Employing such a structure makes it possible to realize both good adhesiveness and wiring resistance.

The semiconductor devices of the first and second embodiments each include the structure in which the Ti content of the barrier metal layer along the bottoms of the wiring trenches and the vias is relatively larger than the Ti content of the barrier metal layer along the sidewalls. As the composition of the barrier metal layer along the bottoms of the wiring trenches, though depending on a formation method of the structure, any of various compositions can be selected within a range in which good adhesiveness is obtained. For example, when importance is put on low resistance, the Ti composition is made small so as to be close to the composition along the sidewalls, and when importance is put on reliability, the Ti composition is made large so as to be close to the composition along the via bottoms.

Though plating is employed for burying the metal wiring layer (Cu wiring layer) in the wiring trenches and the vias in the first and second embodiments, it should be noted that the present invention is not limited to this. It goes without saying that a CVD method or an ALD method may be employed for burying the metal wiring layer. Regarding the formation of the barrier metal, the PVD process is mainly described, but the combination of the PVD method and the ALD method may be employed.

Further, as for the optimum cathode condition, substrate bias value, and gas flow rate, only examples are shown in the embodiments, and they are appropriately selected from a proper range according to a used film forming apparatus. Regarding the structure of the semiconductor device, the film formation method is not limited to the PVD method, the ALD method, and the like. The interlayer insulating film may have a hybrid structure or a monolithic structure.

The present invention is not limited to the above-described embodiments, and is applicable to semiconductor devices with various structures each of which includes a metal wiring layer formed in concave portions of an interlayer insulating film via a barrier metal layer, and to manufacturing method thereof. Such semiconductor devices and manufacturing methods thereof are also included in the present invention. The embodiments of the present invention can be expanded or modified within a range of the technical idea of the present invention, and the expanded or modified embodiments are also included in the technical scope of the present invention.

What is claimed is:

1. A semiconductor device, comprising:
a semiconductor substrate;
an interlayer insulating film, formed above the semiconductor substrate, having a concave portion;
a barrier metal layer, formed along a bottom and a sidewall of the concave portion, having a first portion provided along the sidewall and a second portion provided along the bottom; and
a metal wiring layer formed in the concave portion via the barrier metal layer,
wherein the first portion of the barrier metal layer is composed of a titanium nitride layer whose titanium content in all components except oxygen and a noble metal component is more than 50 at %, and the second portion of the barrier metal layer is composed of a titanium nitride layer whose titanium content in all components except oxygen and a noble metal component is more than 50 at % or composed of a titanium layer, and
wherein a volume average of the titanium content of the second portion is relatively larger than a volume average of the titanium content of the first portion.

2. The semiconductor device according to claim 1,
wherein a nitrogen content in all the components except the oxygen and the noble metal component in the second portion is less than 40 at %.

3. The semiconductor device according to claim 1,
wherein the barrier metal layer has a lamination film including a first titanium nitride film whose titanium content in all components except oxygen and a noble metal component is more than 50 at %, and a second titanium nitride film whose titanium content in all components except oxygen and a noble metal component is larger than the titanium content of the first titanium nitride film or a titanium film laminated with the first titanium nitride film.

4. The semiconductor device according to claim 3,
wherein the second titanium nitride film or the titanium film in the second portion of the barrier metal layer is formed in larger amount than the second titanium nitride film or the titanium film in the first portion of the barrier metal layer.

5. The semiconductor device according to claim 3,
wherein the second portion of the barrier metal layer includes only the second titanium nitride film or the titanium film.

6. The semiconductor device according to claim 1,
wherein the barrier metal layer includes a titanium nitride film whose titanium content in all components except oxygen and a noble metal component is more than 50 at %, and the titanium nitride film in the first portion of the barrier metal layer is nitrided relatively more than the titanium nitride film in the second portion of the barrier metal layer.

7. The semiconductor device according to claim 1,
wherein the concave portion includes a wiring trench and a via communicating with a bottom of the wiring trench, and the barrier metal layer is formed along bottoms and sidewalls of the wiring trench and the via.

8. The semiconductor device according to claim 1,
wherein the metal wiring layer includes a copper wiring film, and the interlayer insulating film includes a low-dielectric insulating film.

9. A method of manufacturing a semiconductor device, comprising:
forming an interlayer insulating film above a semiconductor substrate;
forming a concave portion in the interlayer insulating film;
forming a barrier metal layer along a bottom and a sidewall of the concave portion, comprising:
forming a first titanium nitride film whose titanium content in all components except oxygen and a noble metal component is more than 50 at %, and
forming a second titanium nitride film whose titanium content in all components except oxygen and a noble metal component is larger than the titanium content of the first titanium nitride film or a titanium film so as to form the second titanium nitride film or the titanium film relatively more along the bottom than along the sidewall; and
forming a metal wiring layer in the concave portion via the barrier metal layer.

10. The method of manufacturing the semiconductor device according to claim 9,
wherein the barrier metal layer has a first portion formed along the sidewall and a second portion formed along the bottom, and a nitrogen content in all components except oxygen and a noble metal component in the second portion is less than 40 at %.

11. The method of manufacturing the semiconductor device according to claim 9,
wherein the first titanium nitride film is formed by a sputtering method with a non-nitride mode along the bottom and the sidewall of the concave portion, and the second titanium nitride film is formed by a sputtering method with a non-nitride mode on the first titanium nitride film.

12. The method of manufacturing the semiconductor device according to claim 11,
wherein the second titanium nitride film is formed by employing a condition under which the titanium content of the second titanium nitride film becomes larger than the titanium content of the first titanium nitride film and an amount of the second titanium nitride film formed along the bottom becomes larger than an amount of the second titanium nitride film formed along the sidewall.

13. The method of manufacturing the semiconductor device according to claim 11,
wherein the second titanium nitride film is formed by employing a substrate bias lower than a substrate bias employed when the first titanium nitride film is formed and a nitrogen flow rate lower than a nitrogen flow rate employed when the first titanium nitride film is formed.

14. The method of manufacturing the semiconductor device according to claim 9,
wherein the second titanium nitride film or the titanium film is formed after part of the first titanium nitride film formed along the bottom is etched.

15. The method of manufacturing the semiconductor device according to claim 9,
wherein the second titanium nitride film or the titanium film is formed after the first titanium nitride film formed along the bottom is removed.

16. The method of manufacturing the semiconductor device according to claim 9,
wherein a copper plating film is formed as the metal wiring layer in the concave portion, and the copper plating film is annealed at a temperature of 200° C. or more.

17. A method of manufacturing a semiconductor device, comprising:
forming an interlayer insulating film above a semiconductor substrate;
forming a concave portion in the interlayer insulating film;
forming a barrier metal layer along a bottom and a sidewall of the concave portion, comprising:
forming a titanium nitride film whose titanium content in all components except oxygen and a noble metal component is more than 50 at % or a titanium film, and
nitriding the titanium nitride film or the titanium film by using at least one selected from a nitrogen ion and a nitrogen radical so as to nitride the titanium nitride film or the titanium film formed along the sidewall relatively more than the titanium nitride film or the titanium film formed along the bottom; and
forming a metal wiring layer in the concave portion via the barrier metal layer.

18. The method of manufacturing the semiconductor device according to claim 17,
wherein the barrier metal layer has a first portion formed along the sidewall and a second portion formed along the bottom, and a nitrogen content in all components except oxygen and a noble metal component in the second portion is less than 40 at %.

19. The method of manufacturing the semiconductor device according to claim 17,
wherein the titanium nitride film is formed by a sputtering method with a non-nitride mode.

20. The method of manufacturing the semiconductor device according to claim 17,
wherein a copper plating film is formed as the metal wiring layer in the concave portion, and the copper plating film is annealed at a temperature of 200° C. or more.
